(19) United States
(12) Patent Application Publication
(10) Pub. No.: US 2014/0345682 A1
(43) Pub. Date: Nov. 27, 2014

(54) MODULAR SUPRAMOLECULAR ACTIVE LAYER AND ORGANIC PHOTOVOLTAIC DEVICES

(71) Applicant: UNIVERSITY OF FLORIDA RESEARCH FOUNDATION, INC., Gainesville, FL (US)

(72) Inventors: JIANGENG XUE, GAINESVILLE, FL (US); RONALD KEITH CASTELLANO, GAINESVILLE, FL (US)

(21) Appl. No.: 14/454,353

(22) Filed: Aug. 7, 2014

Related U.S. Application Data
(63) Continuation-in-part of application No. PCT/US2013/025105, filed on Feb. 7, 2013.
(60) Provisional application No. 61/595,963, filed on Feb. 7, 2012.

(51) Int. Cl. H01L 51/42; H01L 51/00

(52) U.S. Cl. CPC H01L 51/4253; H01L 51/0068; H01L 51/0072
USPC 136/255; 252/500; 438/94

(57) ABSTRACT

A photoactive layer for an organic photovoltaic device has a supramolecular assembly of donors or acceptors formed from a plurality of units that are mixed with electron acceptors or electron donors, respectively, to form an ordered or semi-ordered bulk heterojunction structure. Each unit is formed from a plurality of sub-units that are combined and ordered by hydrogen bonding or other non-covalent interactions to form units that by π-stacking and, optionally, other forces are organized into the supramolecular assembly. Each sub-unit includes at least one electron donor or acceptor moiety, at least one non-covalent interacting moiety, and a linking moiety between the non-covalent interacting moiety and the electron donor or electron acceptor moiety of the sub-unit. The organized supramolecular assembly connects donors or acceptors through the thickness of the photoactive layer, and allows parallel continuous electron acceptor or electron donor phases through the thickness of the active layer.

### CROSS-REFERENCE TO RELATED APPLICATIONS

This application is a continuation-in-part of International Patent Application No. PCT/US2013/025105, filed Feb. 7, 2013, which claims the benefit of U.S. Provisional Patent Application Ser. No. 61/595,963, filed Feb. 7, 2012, the disclosures of which are hereby incorporated by reference in their entirety.

### BACKGROUND OF INVENTION

Organic photovoltaics (OPVs) based on semiconducting π-conjugated materials may permit solar cells and other photovoltaic devices that have lower manufacturing costs, are compatible with flexible substrates, are structurally tunable, and are easily processed. In spite of these advantages for developing new materials and device structures, state-of-the-art efficiencies of OPVs are far lower than those their inorganic counterparts display and the efficiencies must be significantly improved if OPV materials are to be introduced into devices with wide scale commercial applications.

Although a number of factors limit the efficiency of existing OPV cells, one persistent challenge lies in designing a material that efficiently generates and transports charge carriers. Central to the most efficient OPV cells is a bulk heterojunction (BHJ) photoactive layer that, ideally, consists of interpenetrating networks of organic donor and acceptor materials formed due to phase separation from blends of inhomogeneous materials, as illustrated in FIG. 1. An ideal BHJ displays a high interfacial area between the two components that leads to efficient charge generation with many transport pathways for percolating electrons and holes. Although various methods have been developed that are directed to optimization of the BHJ morphology, including thermal annealing, solvent annealing, and the use of solvent additives, kinetic processes that govern phase separation inevitably result in bottlenecks, cul-de-sacs, and islands, as illustrated in FIG. 1, which are detrimental to charge transport in the active layer. Optimized processing conditions to form the BHJ may vary widely with the active layer composition and the molecular structure of the components in the composition, but an effective protocol that can be applied to many different organic materials systems and lead to efficient OPV cells by these “top-down” engineering and other nanoscale BHJ fabrication approaches has not been successfully demonstrated. An alternative, “bottom-up” strategy for self-guided BHJ formation that can be extended to known or new materials, that have been optoelectronically optimized, may permit more efficient OPVs from a wider range of active materials with lower fabrication costs.

### BRIEF SUMMARY

Embodiments of the invention are directed to a “bottom-up” designed π-conjugated electron donor or acceptor system where hydrogen-bonding moieties guide the hierarchical assembly of supramolecular assemblies of electron donor or acceptor moieties in π-stacked columnar arrays. The supramolecular donor or acceptor domains persist in the presence of a plurality of electron acceptors or electron donors, forming optimal percolation pathways for electrons and holes in the active layer. These ordered or semi-ordered bulk heterojunction (BHJ) structures decouple the optoelectronic properties of the molecular donor from its morphological/film forming characteristics, and do not rely on the optical/electronic optimization of donor-acceptor pairs for improved efficiencies.

Embodiments of the invention are directed to a photoactive layer, where, for example, a supramolecular assembly of electron donors is mixed with a plurality of electron acceptors. The supramolecular assembly of electron donors is formed from a plurality of units, each of which includes a plurality of one or more sub-units that include at least one electron donor moiety, linked to at least one moiety capable of noncovalent interactions with like moieties from other members of the supramolecular assembly; such non-covalent interacting moieties include hydrogen bonding, ion-pairing, metal coordination, and halogen bonding. The link between the electron donor moiety and non-covalent interacting moiety, referred to as a linking moiety, can be a single, double or triple bond between an atom of the donor moiety and the non-covalent interacting moiety or it can be a unit that comprises at least one atom. The linking moiety can include two functionalities by which the donor moiety is bonded to the linking moiety and the H-bonding moiety is bonded to the linking moiety. The plurality of electron acceptors fill gaps within the supramolecular assembly of donors to form a nanophase separate, but in contact with, the electron donor units of the supramolecular assembly. Continuous parallel nanophases of electron donors from the units for hole percolation and filled gaps of electron acceptors for electron percolation are formed through the photoactive layer. In this manner mixed phases where hole-electron recombination can occur is discouraged throughout the photoactive layer.

### BRIEF DESCRIPTION OF DRAWINGS

FIG. 1 is a drawing that represents charge formation and hole and electron migration in a prior art bulk heterojunction (BHJ) structure.

FIG. 2 shows a representation of a sub-unit having an electron donor moiety covalently linked to an H-bonding moiety, as the non-covalent interacting moiety, through a linking moiety that organizes into units and further organizes as a n-stacked supramolecular assembly of electron donors where fullerene electron acceptors decorate the voids of the assembly to form a BHJ, according to an embodiment of the invention.

FIG. 3 shows a representation of a sub-unit having an electron donor moiety covalently linked to three non-covalent interacting moieties that form an interaction that associates two moieties to form units of extended sheets that organize into a n-stacked supramolecular assembly of electron donors.

FIG. 4 shows exemplary H-bonding moieties, non-covalent interacting moieties, and their homo-assembly into the 3-, 4-, and 6-fold cores that organize sub-units into units, according to an embodiment of the invention.

FIG. 5 shows a) exemplary H-bonding moieties and b) H-bonding partners that hetero-assemble into 3-fold cores to organize sub-units into units, according to an embodiment of the invention.

FIG. 6 shows exemplary electron donor moieties that can be included in sub-units according to an embodiment of the invention.

FIG. 7 shows a BHJ that contains a homo-assembly of sub-units having two H-bonding moieties per sub-unit that organize into sheets and n-stack into assemblies where a fullerene electron acceptor resides within hexagonal voids of the donor assembly, according to an embodiment of the invention.

FIG. 8 shows an organic photovoltaic (OPV) device where the organic active layer comprises a supramolecular assembly of electron donors that is decorated with electron acceptors according to an embodiment of the invention.

FIG. 9 shows a H-bonding moiety employed in a subunit, for an exemplary embodiment of the invention, and the nature of the H-bonding in the units formed by association of three subunits.

FIG. 10 shows a projection from a) the side and b) the top of a portion of the 7-stacked supramolecular assembly of electron donors formed using the MeBQPH sub-unit and its decoration with C₆₀ electron acceptors, according to an embodiment of the invention.

FIG. 11 shows a composite plot of the visible spectra for MeBQPH and MeBQPME subunits in solution and their assembled films, according to an embodiment of the invention.

FIG. 12 shows composite x-ray diffraction patterns for MeBQPH and MeBQPME crystalline powders, and from films of MeBQPH and MeBQPME cast from solution, according to an embodiment of the invention.

FIG. 13 shows an OPV device structure comprising a MeBQPH:C₆₀ photo-responsive layer, according to an embodiment of the invention.

FIG. 14 shows plots of external quantum efficiencies (EQEs) at short-circuit conditions for a MeBQPME:C₆₀ comprising OPV device and a MeBQPH:C₆₀ comprising OPV device of the structure shown in FIG. 13, according to an embodiment of the invention.

FIG. 15 shows a current density-voltage characteristics of the two OPV devices of FIG. 14 in the dark (dashed lines) and under 1 sun simulated AM1.5G solar irradiation, according to an embodiment of the invention.

FIG. 16 shows a reaction scheme for the preparation of 4,4,5,5-Tetramethyl-2-(5″-methyl-5′-(5-methylthiophen-2-yl)-[2,2′:4′,2″-terthiophen]-5-yl)-1,3,2-dioxaborolane (1) as an intermediate in the preparation of MeBQPH and MeBQPME.

FIG. 17 shows a reaction scheme for the preparation of MeBQPH, MeBQPME, MeBQPNMe, HexBQPH, HexBQPME, and HexBQPNME, according to an embodiment of the invention.

FIG. 18 shows a reaction scheme for the preparation of HexLQPH and HexLQPME, according to an embodiment of the invention.

FIG. 19 shows absorbance spectra for (a) HexLQPH and HexLQPME as neat films or in solution, and (b) C₆₀:HexLQPH and C₆₀:HexLQPME films, according to an embodiment of the invention.

FIG. 20 shows: (a) an atomic force micrograph (AFM) 500×500 nm height image of 40 nm thick 1:1 blends of HexLQPME:C₆₀; (b) an AFM 500×500 nm height image of 40 nm thick 1:1 blends of HexLQPH:C₆₀; (c) an AFM 500×500 nm phase image of 40 nm thick 1:1 blends of HexLQPME:C₆₀, according to an embodiment of the invention; and (d) an AFM 500×500 nm phase image of 40 nm thick 1:1 blends of HexLQPH:C₆₀, according to an embodiment of the invention, deposited on a silicon/MoOx surface, where the full scale of (a,b) is 7.5 nm, the full scale of (c,d) is 12V.

FIG. 21 shows plots of: (a) external quantum efficiency for 1:1 blends of HexLQPH:C₆₀; (b) external quantum efficiency for 1:1 blends of HexLQPME:C₆₀; (c) current density vs voltage for 1:1 blends of HexLQPH:C₆₀; and (d) current density vs voltage for 1:1 blends of HexLQPME:C₆₀ with various active layer thicknesses.

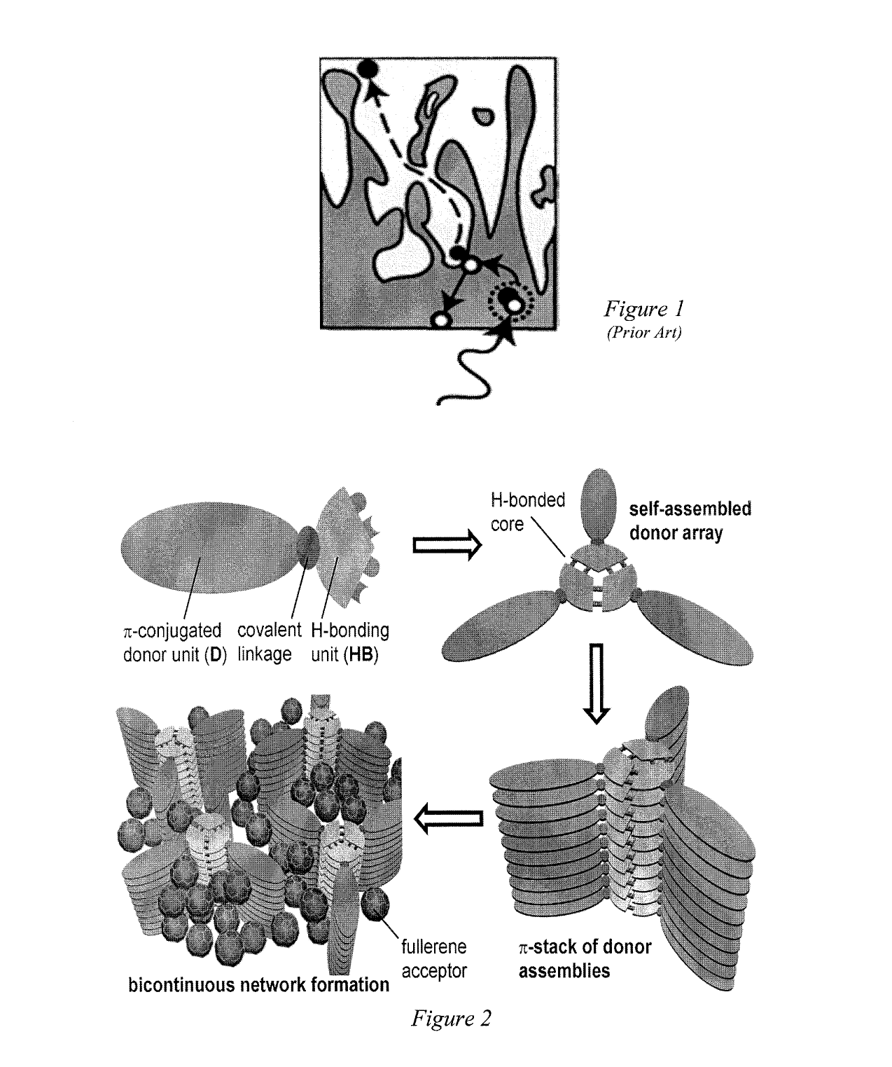

### DETAILED DISCLOSURE

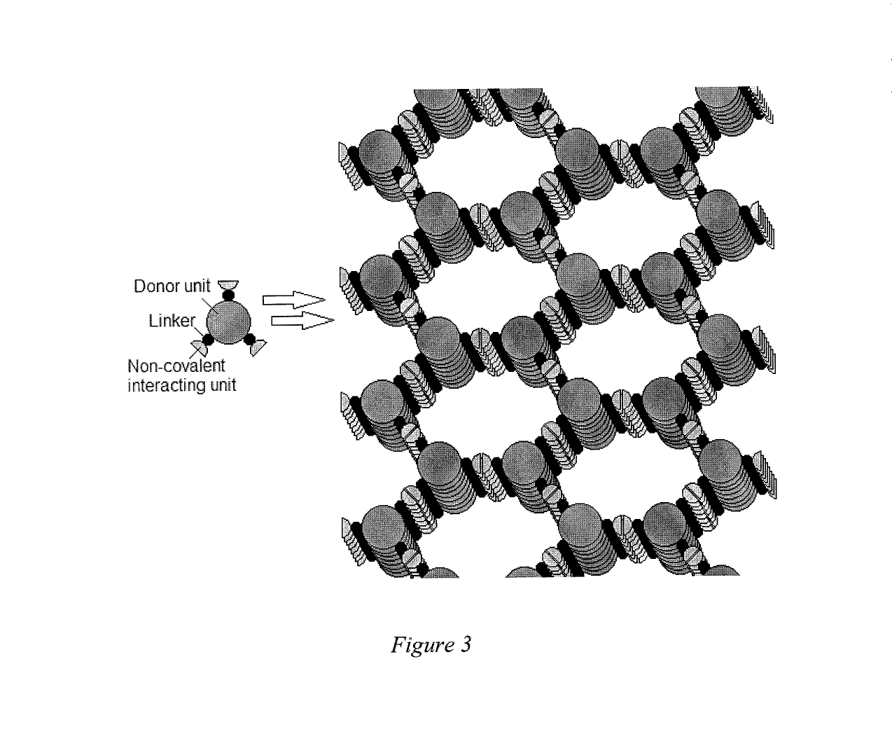

Embodiments of the invention are directed to supramolecular assemblies that organize nanoscale phase separated donors and acceptors and display highly efficient charge generation and transport when used as active layers of organic photovoltaic (OPV) devices. A supramolecular assembly of a donor or an acceptor mixed with a plurality of acceptors or donors, illustrated as fullerene acceptors, is shown schematically in FIG. 2. Although throughout this disclosure, most embodiments of the invention are directed to a supramolecular assembly of donors mixed with a plurality of complementary electron acceptors, a supramolecular assembly of acceptors can be mixed with a plurality of complementary electron donors. The supramolecular assembly is composed of an assembly of units derived from sub-units that comprise three functional components: π-system, represented as a large oval in FIG. 2, that is at least one p-type semiconducting electron donor moiety; at least one non-covalent interacting moiety, represented as a portion of a circle, although not necessarily one third as shown for exemplary purposes, in FIG. 2, to direct assembly of a plurality of sub-units; and at least one linking moiety, represented as a small oval in FIG. 2, that connects a semiconductor moiety to a non-covalent interacting moiety of the sub-unit. The linking moiety can be a bond or bonds between an atom of the semiconductor moiety and the non-covalent interacting moiety, or it can comprise one or more atoms. Although the electron donor moiety is illustrated by an oval in FIG. 2, the electron donor moiety's shape does not need to be one that is similar to an ovular plate. As the π-system is extended over a large portion of the electron donor moiety, a relatively flat surface is common to many, but not necessarily all, of the electron donor moieties that can be used according to embodiments of the invention. The orientation of the electron donor moieties' surfaces does not need to be in the plane that is defined by the associated non-covalent interacting moieties. The electron donor moieties can be monomeric, oligomeric, or polymeric in nature, having one, two, three, four, five, six, seven or more units combined into the electron donor moiety, where three or more units can be combined to have a linear, branched, or multiply branched combination of units.

The non-covalent interacting moieties can associate directly with each other, a homo-assembly, to combine sub-units into units, or the non-covalent interacting moieties can associate with one or more non-covalent interacting partners to form a hetero-assembly of sub-units into units. The sub-units spontaneously form units comprising planar non-covalent interacting aggregates under appropriate conditions by the formation of a plurality of complementary robust non-covalent interactions, such as, H-bonds between hydrogen bonding sites of the hydrogen bonding moieties of the sub-units, alone or in concert with H-bonding partners. Alternatively or in addition to hydrogen bonding moieties, the non-covalent interacting moieties can be those that form halogen bonds, ion-pairing, or metal chelation, alone or in combination with hydrogen bonding or other non-covalent interacting moieties on sub-units. The non-covalent interacting moieties on sub-units can be the same, or can consist of two or more complementary moieties attached to like or complementary linkers and electron donor or other semiconductor moieties, and can employ one or a plurality of different types of non-covalent interactions to form the units. The non-covalent interacting moieties linked to the electron donor moieties can be used in conjunction with complementary non-covalent interacting moieties that lack a semiconductor moiety, for example, a metal ion that associates with non-covalent interacting moieties linked to electron donor moieties by ion-pairing with anionic non-covalent interacting moieties or complexation with ligand comprising sub-units. The units can undergo stacking to form anisotropic π-stacked arrays that are columnar in orientation. Other orientations are possible as long as the orientation provides a definable continuous association of electron donor moieties. An electron donor moiety, or, alternatively, an electron acceptor moiety, can be linked to one or more non-covalent interacting moieties in sub-units such that the π-stacking acts of the donor moieties associate as the core of the units and the non-covalent interacting moieties associate at the outside of the units. For example, as illustrated in FIG. 3, the electron donor moiety can be a circular disk that is linked to three non-covalent interacting moieties linked 120 degrees to each other such that the electron donor moieties are situated in a regular hexagonal pattern to form a unit that is a planar sheet of sub-units with interstitial voids that define columns in the center of the hexagons for the electron accepting moieties of the BHJ.

In embodiments of the invention, the formation of the supramolecular assemblies can be further oriented by including into the sub-units a portion that forms a phase that does not undergo or interfere with the π-stacking or form or interfere with the association of the non-covalent interacting moieties. For example, at least one hydrocarbon moiety that can self-associate only via van der Waals forces can further promote separation from the other portions of the sub-units, such as the non-covalent interacting moieties and electron donor moieties that have stronger specific interactions. The additional promotion of phase separation can further orient the supramolecular assemblies and/or enhance their stability. The hydrocarbon moieties can be aliphatic hydrocarbon chains that are linear, branched, multiply branched, or mixtures thereof. The aliphatic hydrocarbon chains can be of a single size and structure or can be a mixture of sizes and structures. For example, all hydrocarbon moieties can be a single linear C₅-C₂₀ hydrocarbon. The aliphatic hydrocarbon can be interrupted one or more times by an oxygen, sulfur, or other heteroatom that can provide a relatively weak induced dipole within the hydrocarbon moiety as long as it does not inhibit the association of the non-covalent interacting moieties as a ligand or hydrogen bond acceptor. Additionally, the hydrocarbon moiety can promote solubility of the sub-units to facilitate the preparation of the supramolecular assemblies.

As illustrated in FIG. 2, a supramolecular assembly forms that has a plurality of columnar π-stacked arrays with voids within and between the columns that are filled with a fullerene comprising molecule or other n-type semiconductor. These n-type semiconductors serve as electron acceptors in a “bottom up” designed bulk heterojunction (BHJ) for use in OPV devices where the BHJ is ordered or semi-ordered for optimal pathways for percolation of electrons and holes in the active layer. In an embodiment of the invention, the planar nature of the units promotes the evolution of the columnar π-stacked arrays that are perpendicular to the substrate upon which they are formed. The π-stacked arrays and the electron acceptors situated primarily between the π-stacked arrays allow for parallel continuous nanophases of electron donors for hole percolation, and electron acceptors for electron percolation through the photoactive layer. In this manner hole-electron recombination is inhibited, as hole transport can occur through the electron donor phase that is not interrupted by electron acceptor phase containing electrons that is situated between the site of hole-electron formation and the anode of a device, as is common to random interfaced BHJ structures of prior art “top down” BHJs, where hole-electron recombination limits the photocurrent of an OPV device.

Embodiments of the invention are directed to a method of preparing BHJs, where sub-units undergo association into supramolecular assemblies, and directed to OPV devices comprising the BHJs formed with supramolecular assemblies of electron donors decorated with electron acceptors. The preparation of OPV devices, according to embodiments of the invention, is a self-guided modular supramolecular approach to BHJ engineering that is a fundamental departure in formation and structure to that of BHJs formed by presently employed methods where BHJs have randomly dispersed phases, which characterize existing OPVs. In this manner, the optoelectronic properties of the molecular donor are decoupled from its morphological/film forming characteristics, which allow inclusion of any donor structure yet permits optical and/or electronic optimization of an active layer of an OPV device because of the designed donor-acceptor interfaces within the BHJ. The formation of the supramolecular assembly and the BHJ can involve either vapor deposition or solution processing of the active layer.

BHJ OPV devices based on small molecule organic donors have displayed photovoltaic conversion efficiencies in excess of 5% and have advantages common to small molecular systems over polymeric systems that include: ease and cost of obtaining rigorously purified material; adaptability to diverse active layer processing methods; and amenability to molecular-level design of tailored bulk and interface structures. In one embodiment of the invention, sub-units comprise a p-type semiconductor that is a moiety derived from known molecular donors, where the donor is optically and electronically well-matched to a fullerene or other electron acceptor for OPV applications. One or more electron donor moieties are combined in the sub-unit with one or more non-covalent interacting moieties, which ultimately direct the BHJ structure in multiple dimensions over multiple length scales, yet the sub-units retain the advantages over the polymeric systems as to their ease of purification, deposition and design flexibility.

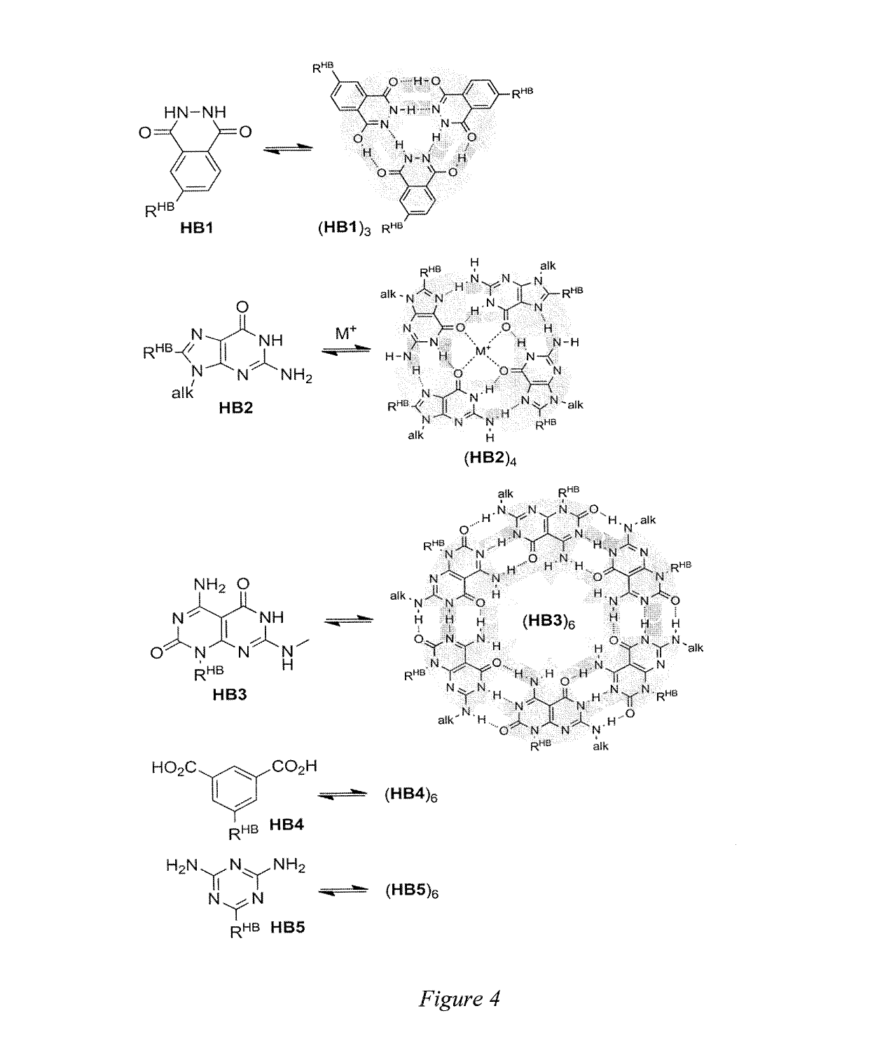

In exemplary embodiments of the invention, non-covalent interacting moieties are H-bonding moieties that allow rod-shaped, disk-shaped or network self-assembly and are easily linked covalently to one or more electron donor moieties. FIG. 4 shows exemplary H-bonding moieties HB1 through HB5 that persist in solution, on surfaces, and/or in the bulk and then form H-bonded assemblies. These H-bonding moieties can further organize into i-stacked columnar arrays with the additional components of the sub-units. These H-bonding moieties form cores for the assembled units that vary in diameter from about 2 to about 4 nm or more and display, for example, 2-, 3-, 4-, or 6-fold symmetry, although other symmetries are possible. Specifically illustrated in FIG. 4 are: the lactam-lactam trimers of HB1; the guanine quartets of HB2; and the hexameric rosettes of HB3, HB4, and HB5. The H-bonding moieties can be derived from any precursor molecule that has complementary H-bonding functionalities that are positioned within the molecule to allow a plurality of H-bonding moieties to associate in a planar manner that promotes the formation of units, and where the precursor molecule has a least one functionality for covalent or ionic connection of an electron donor moiety through a linking moiety of the ultimate sub-unit. The linking moiety can be a single bond, double bond, triple bond between an atom of the semiconductor moiety and an atom of the H-bonding moiety, or it can comprise one or more atoms having, effectively, two functionalities, where the functionalities are defined by bonds formed between an atom exclusive to the linking moiety, one to an atom of the semiconductor moiety and another to an atom of the H-bonding moiety. The functionalities can be those that form by reaction between complementary reactive functionalities on a linking moiety precursor and reactive functionalities of the H-bonding moiety precursor and the electron donor moiety precursor.

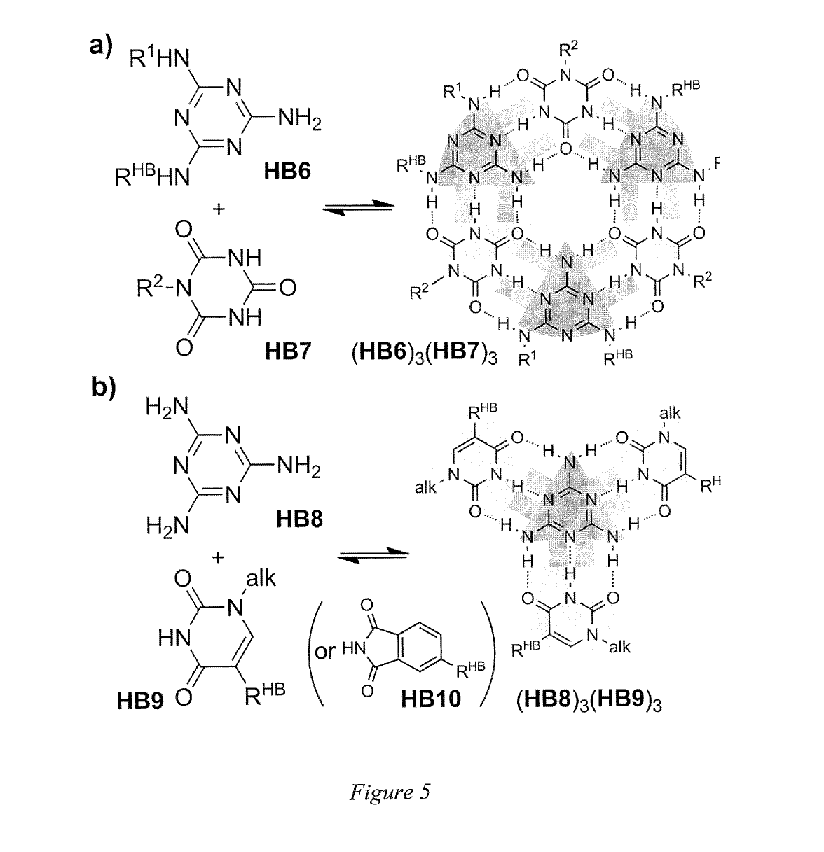

In an embodiment of the invention, rod-shaped, disk-shaped, or network assemblies form when the H-bonding units associate with one or more H-bonding partner to form a hetero-assembly, for example, as illustrated by complementary H-bonding between cyanuric acid-triazine molecules in FIG. 5a. FIG. 5a shows a plurality of differentially-functionalized triazine based sub-units (HB6) and a plurality of their cyanuric acid H-bonding partners HB7, both of which are readily accessible through state of the art substitution chemistry, being combined to form the core of a unit where the electron donor moieties are attached at the R^{HB} sites. Additional positions of the H-bonding moieties that can be optionally substituted are indicated as R¹ and R² on the H-bonding moieties of the sub-unit, are any chemical unit that facilitates processing of the materials by solution techniques or vapor techniques while achieving a desired organization in the active layer. The substitution for R¹ and R² can be selected in a manner that allows optimization of phase segregation by including, for example, alkyl chains of different lengths/branching or fullerene “phase compatiblizers,” which are substituents that have specific and favorable interaction with the fullerene acceptors of the active layer. As shown in FIG. 5, the R^{HB} sites can be the sites of the fullerene “phase compatiblizers” and the R² units may be the sites of attachment of the electron donor moieties. These optional sites of substitution can be used to include other electron donor moieties into the sub-units or to employ the H-bonding partner as a second sub-unit having the same or a different electron donor moiety, for example, one that absorbs a different portion of the solar spectrum than the electron donor moiety of the first sub-unit. Another exemplarily complementary hetero-assembly is shown in FIG. 5b, where a plurality of subunits, exemplarily illustrated by uracil-(HB9) or indole (HB10)-functionalized sub-units, associate with a single H-bonding partner, exemplarily illustrated by melamine (HB8), which acts as a template for formation of the units from the sub-units.

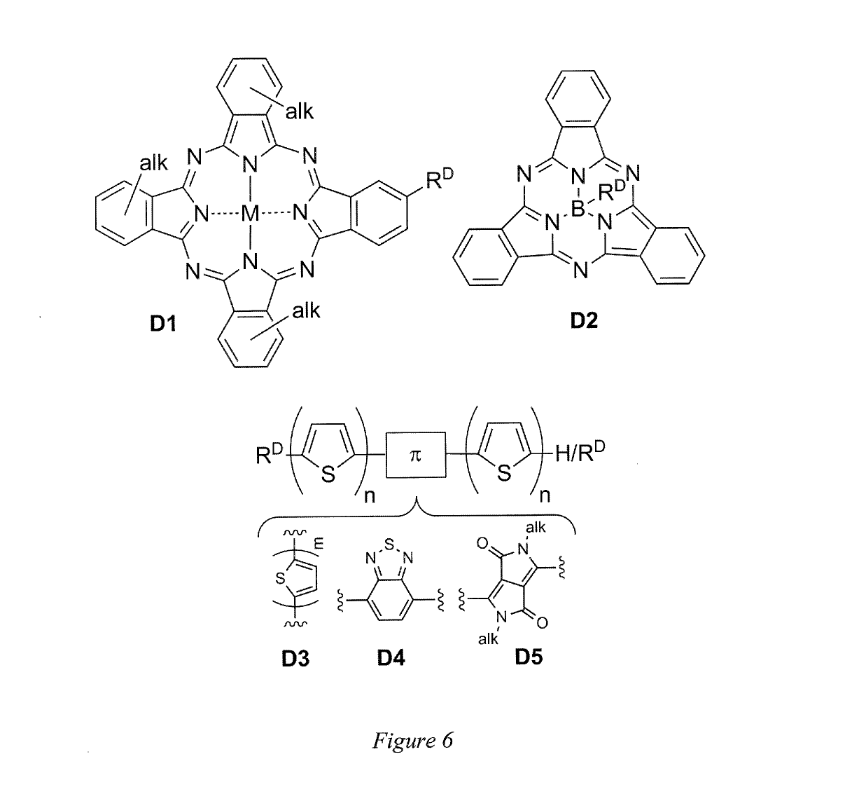

Electron donor moieties, for example, those illustrated in FIG. 6, can be derived from any small molecule or oligomer precursor that has a broad absorption over a suitable range of the solar spectrum and has orbital energies that allow electron transfer to an appropriate acceptor, for example, one matched to a C₆₀ acceptor. Those matched to a C₆₀ acceptor include, but are not limited to, phthalocyanine D1, boron subphthalocyanine D2, oligothiophenes D3, donor-acceptor thiophene-containing oligomers D4 and D5, naphthalocyanine, linear acenes (such as pentacene and tetracene), diindenoperylene, and any derivatives thereof.

In an embodiment of the invention, units comprising a multiplicity of sub-units in the form of a network can occur upon homo- or hetero-association of subunits when at least one sub-unit bears a plurality of hydrogen bonding moieties, as illustrated in FIG. 7 for the homo-assembly of sub-units of a single structure having two H-bonding moieties per sub-unit. As shown in FIG. 7, pores having one or more repeating dimensions can be dictated by the size of the sub-unit and the orientation of the electron donor moiety when the H-bonding moieties are associated.

The supramolecular assembly formation occurs upon hydrogen bonding between the subunits and can be carried out in the presence of the acceptor to directly form an active layer, or the supramolecular assembly of donors can be formed in the absence of acceptors and subsequently filled with acceptors. In one embodiment of the invention, the assembly occurs from solution when a desired temperature or a desired concentration of sub-units is achieved, an H-bonding inhibitor is removed, or when any other mechanism can be controlled in any desired manner to permit manipulation of the sub-units prior to formation of the assembly. In another embodiment of the invention, a vapor phase deposition of the sub-units to a surface can be employed to form a film. The formation of the supramolecular assembly can be followed by one or more analytical techniques including: ¹H NMR; UV/Vis spectroscopy; fluorescence spectroscopy; and/or IR spectroscopy, which may be complemented by mass spectrometry (MS) studies. One or more of these techniques can indicate, for example, H-bond formation, π-stacking, and the dimensionality of the assemblies. The redox behavior of the supramolecular assembly absent the acceptors can be characterized by cyclic voltammetry (CV) and the assemblies' HOMO/LUMO energies and HOMO-LUMO energy gaps can be determined from the measurements such that the appropriate electron acceptors can be chosen.

Films of the supramolecular assembly have identifying spectroscopic and morphological signatures, even in the absence of the acceptors. Embodiments of the invention are directed to methods for solution deposition of the supramolecular assembly by spin coating, inkjet printing, spray coating or other solution deposition or coating methods. Embodiments of the invention are directed to methods for vacuum or vapor phase deposition, for example, vacuum thermal evaporation of sub-units, which results in the growth of thin films in a clean and dry environment where the thickness of the film is readily controlled. The substrate temperature at which deposition of the sub-units occurs can be varied as needed, typically from about room temperature to about 150° C., to yield supramolecular assemblies that have varied packed structures based on the kinetics of deposition and redistribution of the sub-units on the surface during the assembly process. In embodiments of the invention, a supramolecular assembly film can be annealing at elevated temperatures and/or in the presence of an agent to promote redistribution of the H-bonding sites to achieve a desired supramolecular assembly structure that approaches a thermodynamic minimum structure in a reproducible manner.

In one embodiment of the invention, a homeotropic (face-on) alignment of the electro donor units and acceptors of the active layer is formed, promoting efficient charge transport and/or extraction in OPV devices containing these active layers of supramolecular assembly donors and acceptors. In an embodiment of the invention, units form from the sub-units while forming columnar assemblies of units, where the assembly structure persists after donor-acceptor aggregation that occurs by solution or vacuum deposition of acceptors to a preformed supramolecular assembly of donors. In another embodiment of the invention, a solution or vapor co-deposition of sub-units and acceptors is carried out. For example, in an exemplary embodiment, C₆₀ is co-evaporated with sub-units at high vacuum. In another exemplary embodiment, [6,6]-phenyl-C₆₁-butyric acid methyl ester (PCBM) is blended with a sub-unit in solution and deposited on a substrate. Other electron acceptors that can be used according to embodiments of the invention include, but are not limited to: phenyl-C₇₁-butyric-acid-methyl ester (bis[70]PCBM); CdSe nanoparticles; CdS nanoparticles; PbSe nanoparticles; ZnO nanocrystals; titania; electron-deficient pentacenes; terrylene-3,4:11,12-bis(dicarboximide) (TDI); 3,4,9,10-perylenetetracarboxylic-bis-benzimidazole (PTCBI), perylene-3,4,9,10-tetracarboxylic-3,4,9,10-dianhydride (PTCDA), and perylene-3,4,9,10-tetracarboxylic-3,4,9,10-diimide (PTCDI); poly((9,9-dioctylfluorene)-2,7-diyl-alt-[4,7-bis(3-hexylthien-5-yl)-2,1,3-benzothiadiazole]-2,2-diyl) (F8TBT); or 1,4-diaminoanthraquinone (1,4-DAAQ).

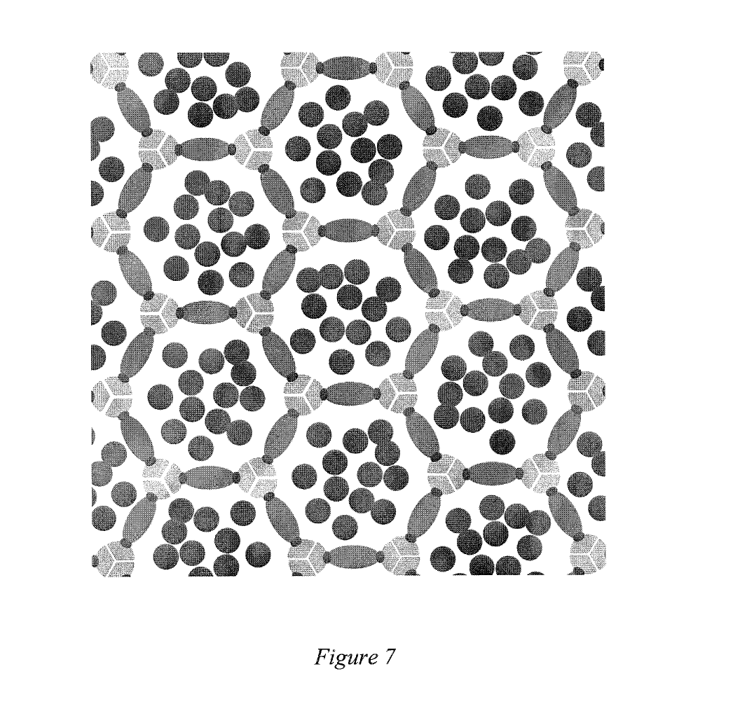

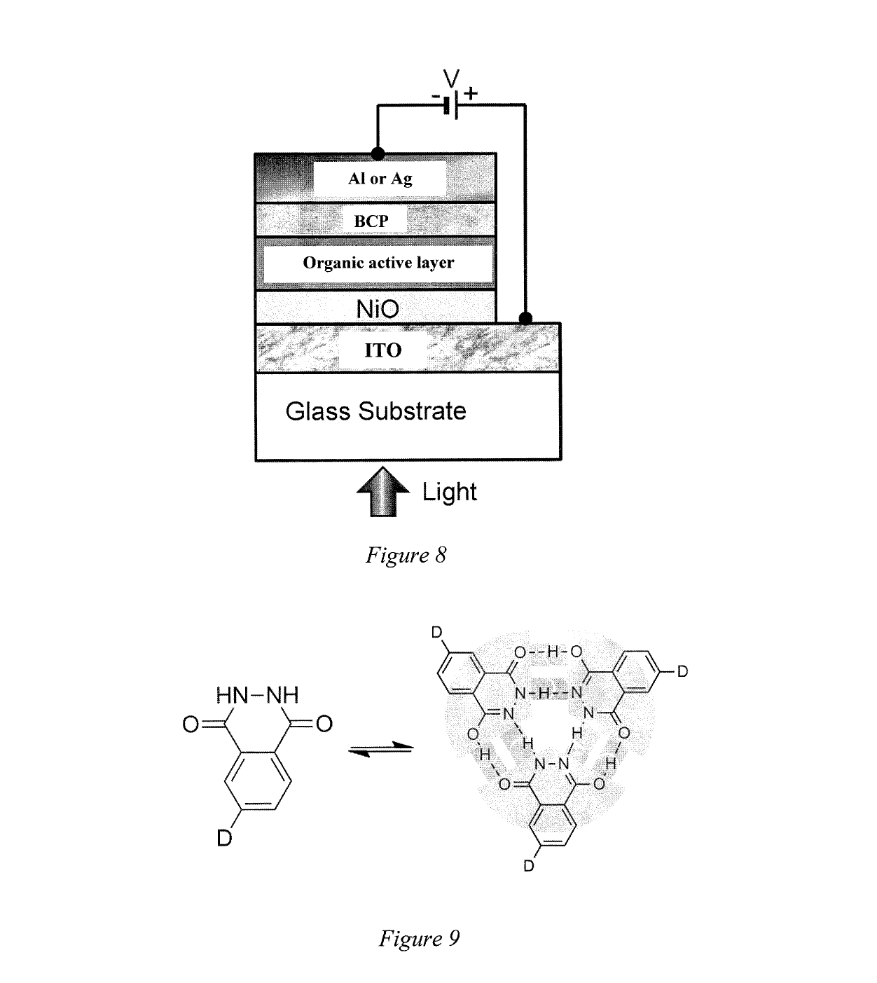

In an embodiment of the invention, the supramolecular assembly of donors with acceptors comprises an active layer for an OPV cell. Vacuum-deposited small molecule sub-units and acceptors or solution-deposited sub-units and acceptors form active layers for an OPV that has a layer structure, as shown schematically in FIG. 8 for an exemplary OPV, according to an embodiment of the invention. As shown in FIG. 8, a glass substrate coated with a transparent conductor, for example, indium-tin-oxide (ITO), which functions as the anode, is coated with a thin (5-40 nm) NiO electron-blocking layer that becomes the substrate for deposition of the active layer comprising the supramolecular assembly according to an embodiment of the invention. In this exemplary embodiment, a bathocuproine (BCP) hole-blocking layer is formed on the active layer, and a cathode layer is formed on the BCP layer by the thermal evaporation in high vacuum of Al or Ag. Substrates for the OPV devices can be any glass, ceramic, organic polymer, inorganic polymer, or metal. The OPV device has at least one transparent electrode, which can be on a transparent substrate or on the face of the device opposite an opaque substrate. The transparent electrode can function as the anode or as the cathode. The transparent electrode can be: tin-doped indium oxide (ITO); fluorine-doped tin oxide (FTO); aluminum-doped zinc oxide (AZO); gallium doped zinc oxide (GZO); graphene; carbon nanotubes; conductive polymers, such as polyethylenedioxythiophene:polystyrenesulfonate (PEDOT:PSS); metal oxide/metal/metal oxide multi-layers, such as MoOₓ/Au/MoOₓ; metallic gratings; or metallic nanowire networks. In addition to NiO, many other p-type, wide-gap oxides or organic semiconductors can be used as the electron-blocking layer. Hole-blocking layers that can be used include, but are not limited to: ZnO; Bathophenanthroline (BPhen); and ruthenium (III) acetylacetonate (Ru(acac)₃).

### Materials and Methods

The molecule MeBQPH having the structure:

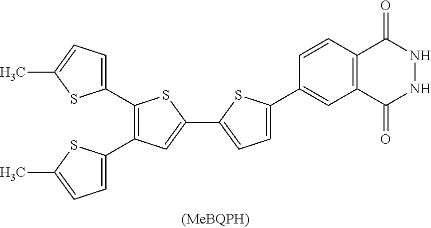 [SMILES: Cc1ccc(-c2cc(-c3ccc(-c4ccc5c(=O)[nH][nH]c(=O)c5c4)s3)sc2-c2ccc(C)s2)s1]

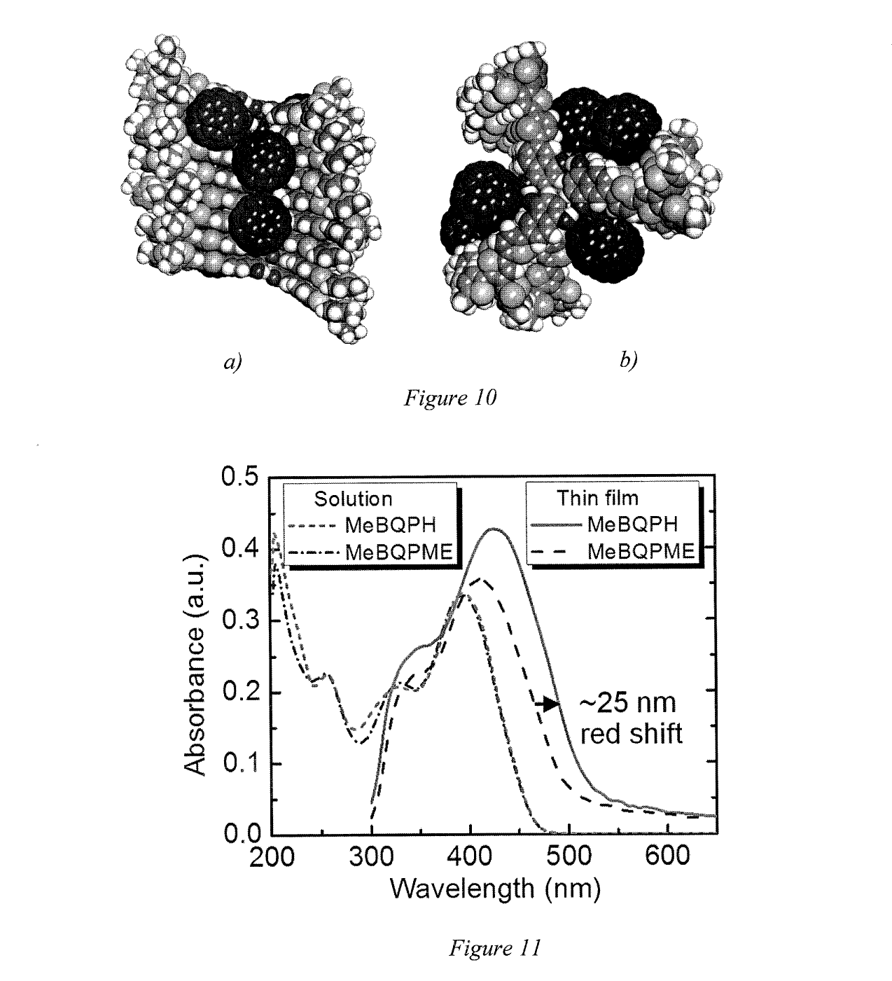

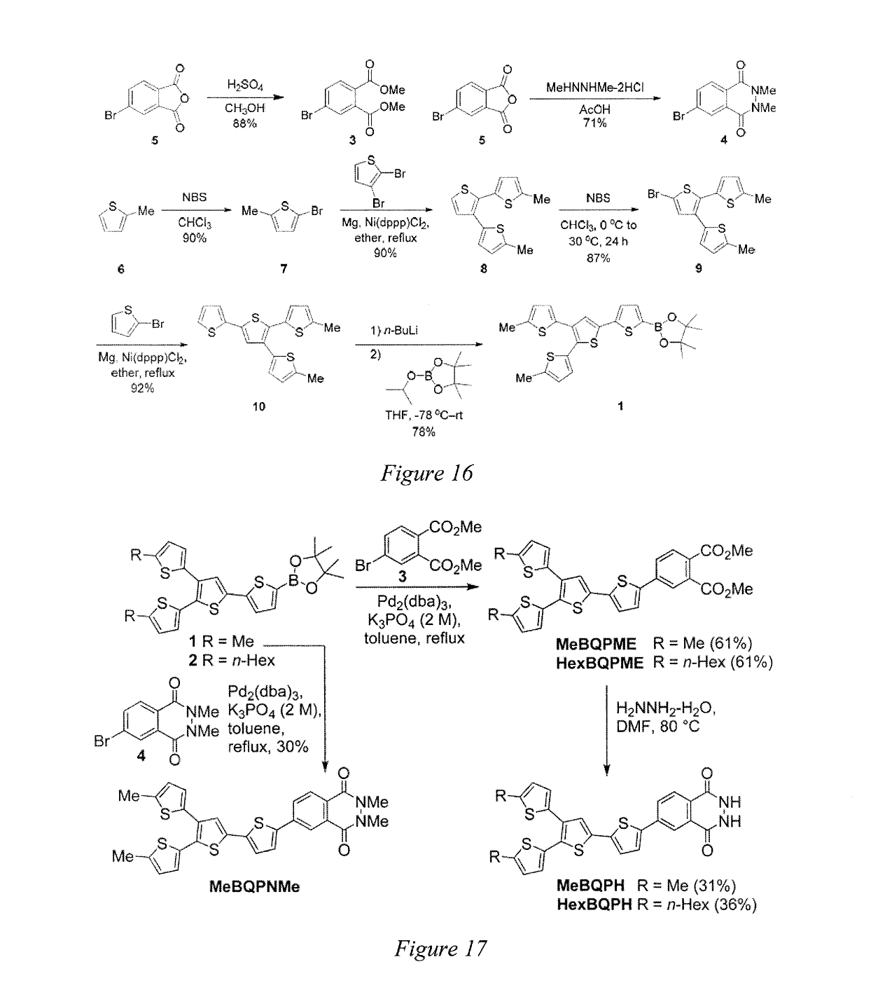

was prepared, as shown in FIGS. 16 and 17, by covalently bonding a branched quaterthiophene electron donor moiety to the hydrogen-bonding moiety phthalhydrazide, where the covalent bond is the linking moiety. The lactim-lactam tautomer form of the hydrazide undergoes formation of a trimer by hydrogen bonding (O . . . H—O and N . . . H—N) as shown in FIG. 9, which promotes the stacking of the MeBQPH sub-units through π-π interactions into units. FIG. 10 shows a computer model of stacked MeTHP trimer units decorated by the electron acceptor C₆₀ molecules in the space between the extended donors the stacked units from a) the side and b) the top.

For comparison, similar molecules MeBQPME and MeBQPNMe, below, were constructed, as shown in FIGS. 16 and 17, to be identical with the MeBQPH with the exception that they lack a hydrogen bond donor functionality such that they lack a non-covalent interacting moiety. The similar MeBQPH and MeBQPME molecules display nearly identical optical absorption spectra in dilute solution, as shown in FIG. 11. In contrast, thin films of the MeBQPH and MeBQPME, as deposited using a high-vacuum thermal evaporation method, show a significant red-shift in their absorption spectra relative to the solution spectra. The spectrum of MeBQPH has a more pronounced red shift, of 25 nm more, than does MeBQPME, as shown in FIG. 13, which can be attributed to the stacking of the molecules in the solid state:

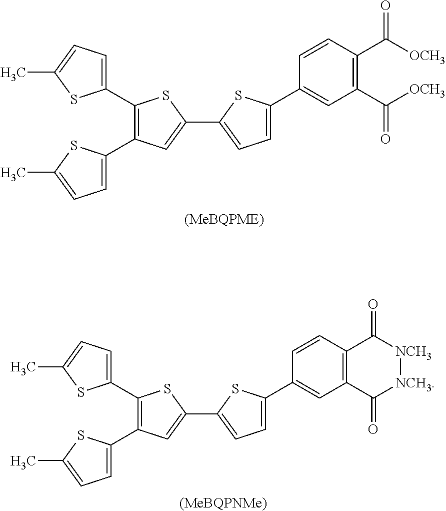

### Synthesis of MeBQP compounds

### Dimethyl-4-bromophthalate (3)

To a solution of 4-bromophthalic anhydride (5) (1.14 g, 5.00 mmol) in methanol (10 mL), concentrated H₂SO₄ (18 M, 0.5 mL) was added dropwise and the reaction mixture was heated to reflux for 24 h. After cooling, the organic substance was extracted with methylene chloride (150 mL), followed by washing with saturated NaHCO₄ solution (50 mL), dried over MgSO₄, and concentrated under reduced pressure. The product was obtained without further purification as white solid in 88% yield (1.2 g): ¹H NMR (CDCl₃): δ 7.84 (d, J=1.7 Hz, 1H), 7.69 (dd, J=8.2, 1.8 Hz, 1H), 7.63 (d, J=8.3 Hz, 1H), 3.91 (d, J=3.8 Hz, 6H) ppm; ¹³C NMR (CDCl₃): δ 167.5, 167.3, 134.6, 134.5, 132.4, 131.1, 130.8, 126.3, 53.5, 53.3 ppm.

### 2-Bromo-5-methylthiophene (7)

In the absence of light, 2-methylthiophene (6) (1.00 mL, 10.3 mmol) was added to a solution of N-bromosuccinimide (2.07 g, 11.4 mmol) in chloroform/acetic acid (10 mL of a 1:1 solution). The resulting solution was stirred at 0° C. for 1 h. The mixture was then allowed to warm to room temperature and stirred for an additional 12 h. The reaction was quenched with aqueous NaOH. The organic layer was separated, washed with water, and dried over MgSO₄. The product was distilled under reduced pressure and obtained as a pale yellow oil in 75% yield (1.4 g): ¹H NMR (CDCl₃, 500 MHz): δ 6.82 (d, J=3.6 Hz, 1H), 6.51 (d, J=3.6, 1H), 2.42 (s, 3H) ppm; ¹³C NMR (CDCl₃): δ 141.5, 129.7, 125.6, 108.7, 15.6 ppm.

### 5,5″-Dimethyl-2,2′:3′,2″-terthiophene (8)

Under argon, 2-bromo-5-methylthio-phene (7) (3.97 g, 22.4 mmol) was added dropwise to a suspension of iodine and magnesium turnings (0.63 g, 26 mmol) in dry diethyl ether (20 mL) to form the Grignard reagent. The resulting solution was heated to reflux for 1 h. After cooling to room temperature, the Grignard reagent was then slowly added to a mixture of 2,3-dibromothiophene (2.85 mL, 25.2 mmol) and [1,3-bis(diphenylphosphino)propane]dichloronickel(II) (Ni(dppp)₂Cl₂, 160 mg, 0.30 mmol) in diethyl ether (100 mL) at 0° C. under argon. The resulting mixture was heated to reflux for 24 h and then quenched with 1M HCl (10 mL). The mixture was extracted with diethyl ether (300 mL). The organic layers were combined, washed with water, dried over MgSO₄, and concentrated under reduced pressure. The product was purified by flash column chromatography (petroleum ether) and obtained as a green oil in 90% yield (5.52 g): ¹H NMR (CDCl₃, 300 MHz): δ 7.22 (d, J=5.2 Hz, 1H), 7.13 (d, J=5.2 Hz, 1H), 6.95 (d, J=3.2 Hz, 1H), 6.88 (d, J=3.2 Hz, 1H), 6.68 (dd, J=2.4 Hz, J=2.4 Hz, 2H), 2.49 (s, 6H) ppm.

### 5′-Bromo-5,5″-dimethyl-2,2′:3′,2″-terthiophene (9)

In the absence of light, 5,5″-dimethyl-2,2′:3′,2″-terthiophene (8) (1.45 g, 5.25 mmol) was added to a solution of N-bromosuccinimide (1.01 g, 5.67 mmol) in chloroform, and the resulting solution was stirred at 0° C. for 1 h. The mixture was allowed to warm to room temperature and stirred for 12 h. The mixture was then warmed to 30° C. and allowed to react for an additional 24 h. The reaction was quenched with aqueous NaOH. The organic layer was separated, washed with water, dried over MgSO₄, and concentrated under reduced pressure. The product was then purified by flash column chromatography (hexanes) and obtained as a green oil in 88% yield (1.64 g): ¹H NMR (CDCl₃): δ 7.07 (s, 1H), 6.89 (d, J=3.4 Hz, 1H), 6.82 (d, J=3.4 Hz, 1H), 6.66 (d, J=2.5 Hz, 1H), 6.63 (d, J=2.4 Hz, 1H), 2.46 (s, 3H), 2.45 (s, 3H) ppm; ¹³C NMR (CDCl₃, 500 MHz, determined via gHMBC): δ 142.6, 141.7, 140.1, 138.9, 133.6, 132.0, 131.0, 128.1, 126.2, 125.8, 125.6, 105.0, 16.5, 15.4 ppm; HRMS (MALDI-TOF) calculated 354.9100 for C₁₄H₁₀S₃Br (M−H)⁺. found 354.9106.

### 5,5″-Dimethyl-5′-(thiophen-2-yl)-2,2′,3′,2″-terthiophene (10)

Under argon, 2-bromothiophene (10.3 g, 63.3 mmol) was added dropwise to a suspension of iodine and magnesium (1.52 g, 63.3 mmol) in dry diethyl ether (20 mL) to form the Grignard reagent. The resulting solution was heated to reflux for 1 h. After cooling to room temperature, the Grignard reagent was slowly added to a mixture of 5′-bromo-5,5″-dimethyl-2,2′:3′,2″-terthiophene (9) (13 g, 37 mmol) and [1,3-bis(diphenylphosphino)propane]dichloronickel(II) (Ni(dppp)2Cl2, 198 mg, 0.36 mmol) in dry diethyl ether (100 mL) at 0° C. under argon. The resulting mixture was heated to reflux for 24 h and quenched with dilute 1M HCl (10 mL). The mixture was extracted with diethyl ether (300 mL), The organic layers were combined, washed with water, dried over MgSO₄, and concentrated under reduced pressure. The product was then purified by flash column chromatography (hexanes) and obtained as a yellow liquid in 92% yield (12 g): ¹H NMR (CDCl₃): δ 7.40 (s, 1H), 7.35 (m, 2H), 7.17 (m, 3H), 6.86 (m, 2H), 2.65 (dd, J=7.7, 1.1 Hz, 6H) ppm; ¹³C NMR (CDCl₃): δ 141.3, 140.0, 136.6, 135.2, 134.8, 132.4, 132.3, 130.3, 127.9, 127.8, 126.7, 126.1, 125.5, 125.4, 124.6, 123.9, 15.31, 15.28 ppm; HRMS (APCI-TOF) calculated 359.0051 for C₁₈H₁₄S₄ (M+H)⁺. found 359.0065.

### 4,4,5,5-Tetramethyl-2-(5″-methyl-5′45-methylthiophen-2-yl)-[2,2′:4′,2″-terthio-phen]-5-yl)-1,3,2-dioxaborolane (1)

Under argon, n-butyllithium in hexane (2.5 M, 4.4 mL, 11 mmol) was added to a solution of 5,5″-dimethyl-5′-(thiophen-2-yl)-2,2′,3′,2″-terthiophene (10) (3.9 g, 10 mmol) in dry THF (150 mL) at −78° C. and the mixture was stirred at this temperature for 2 h. 2-Isopropoxy-4,4,5,5-tetramethyl-[1,3,2]-dioxaborolane (2.2 mL, 11 mmol) was added, and the reaction mixture was warmed to room temperature and stirred for an additional 12 h. The reaction was then quenched with brine (50 mL) and the product was extracted with diethyl ether. The organic layers were combined, washed with water, dried over MgSO₄, and concentrated under reduced pressure. The crude product was purified by gradient flash column chromatography (0-20% dichloromethane in hexane) to give the product as a green liquid in 79% yield (3.8 g): ¹H NMR (CDCl₃): δ 7.58 (d, J=4.0 Hz, 1H), 7.28 (s, 1H), 6.99 (d, J=3.2 Hz, 1H), 6.93 (d, J=3.3 Hz, 1H), 6.70 (d, J=2.5 Hz, 2H), 2.52 (d, J=4.0 Hz, 6H), 1.39 (s, 12H) ppm; ¹³C NMR (CDCl₃): δ 143.1, 141.3, 140.0, 137.7, 134.8, 134.5, 132.2, 132.0, 130.8, 127.6, 126.5, 126.4, 125.3, 125.1, 124.8, 83.9, 24.5, 15.2, 15.1 ppm; HRMS (APCI-TOF) calculated 485.0908 for C₂₄H₂₅BO₂S₄ (M+H)⁺. found 485.0908.

### Dimethyl-4-(5″-methyl-5′-(5-methylthiophen-2-yl)[2,2′:4′,2″-terthiophen]-5-yl) phthalate (MeBQPME)

Under argon, degassed toluene (15 mL) was added to a suspension of 4,4,5,5-tetramethyl-2-(5″-methyl-5′-(5-methylthiophen-2-yl)-[2,2′:4′,2″-terthiophen]-5-yl)-1,3,2-dioxaborolane (1) (1.5 g, 3.1 mmol), potassium phosphate tribasic (K₃PO₄, 2 M aqueous solution, 10 mL), tris(dibenzylideneacetone)dipalladium(0) (Pd₂(dba)₃, 21 mg), tri-tert-butylphosphonium tetrafluoroborate ((tBu)₃P—HBF₄, 27 mg) and dimethyl-4-bromophthalate (3) (1.3 g, 4.5 mmol). The solution was heated to reflux for 24 h. After cooling to room temperature, the mixture was poured into water and extracted with methylene chloride. The organic layers were combined, washed with water, dried over MgSO₄, and concentrated under reduced pressure. The product was purified by flash column chromatography (petroleum ether/CH₂Cl₂, 1:1) and obtained as a yellow solid in 61% yield (1.04 g): ¹H NMR (CDCl₃): δ 7.86 (d, J=1.7 Hz, 1H), 7.82 (d, J=8.1 Hz, 1H), 7.72 (dd, J=8.1, 1.8 Hz, 1H), 7.35 (d, J=3.9 Hz, 1H), 7.20 (s, 1H), 7.17 (d, J=3.9 Hz, 1H), 6.96 (d, J=3.6 Hz, 1H), 6.91 (d, J=3.5 Hz, 1H), 6.68 (d, J=3.2 Hz, 2H), 3.95 (d, J=9.9 Hz, 6H), 2.49 (d, J=5.0 Hz, 6H) ppm; ¹³C NMR (CDCl₃): δ 168.2, 167.1, 141.6, 140.4, 140.3, 137.9, 137.1, 134.6, 134.5, 133.7, 132.4, 132.2, 131.1, 130.1, 129.2, 127.9, 127.0, 126.9, 126.6, 125.8, 125.6, 125.4, 125.1, 124.9, 52.8, 52.6, 15.42, 15.38 ppm; HRMS (ESI-TOF) calculated 551.0474 for C₂₈H₂₂O₄S₄ (M+H)⁺. found 551.0491; elemental analysis calculated C, 61.07; H, 4.03. and found C, 61.13; H, 3.74.

### 6-(5″-Methyl-5′-(5-methylthiophen-2-yl)-[2,2′:4′,2″-terthiophen]-5-yl)-2,3-di-hydrophthalazine-1,4-dione (MeBQPH)

Under argon, anhydrous hydrazine (2.42 mL, 50 mmol) was added to a solution of dimethyl-4-(5″-methyl-5′-(5-methylthiophen-2-yl)-[2,2′;4′,2″-terthiophen]-5-yl)phthalate (MeBQPME) (0.55 g, 1.0 mmol) in DMF (40 mL). The reaction mixture was heated at 80° C. for 24 h. The mixture was then cooled to 0° C. and ethanol (40 mL) was added. The yellow precipitate formed was isolated by filtration. The precipitate was recrystallized from DMF-ethanol (1:1) to yield the product as a dark orange solid in 31% yield (400 mg): ¹H NMR (DMSO-d₆): δ 11.61 (s, 2H), 8.22 (d, J=8.8 Hz, 2H), 8.09 (d, J=8.4 Hz, 1H), 7.81 (d, J=3.9 Hz, 1H), 7.54 (s, 1H), 7.48 (d, J=3.8 Hz, 1H), 7.09 (d, J=3.5 Hz, 1H), 7.04 (d, J=3.5 Hz, 1H), 6.81 (m, 2H), 2.44 (d, J=5.2 Hz, 6H) ppm; ¹³C NMR (DMSO-d₆): δ 162.3, 141.8, 140.7, 140.2, 136.8, 136.7, 134.2, 133.5, 132.6, 130.8, 129.6, 129.1, 128.7, 127.4, 127.2, 126.5, 126.2, 126.1, 125.7, 120.6, 15.0, 14.9 ppm; HRMS (DART-TOF) calculated 519.0324 for C₂₆H₁₈N₂O₂S₄ (M+H)⁺. found 519.0321; elemental analysis calculated N, 5.40; C, 60.21; H, 3.50 and found N, 5.50; C, 59.95; H, 3.76.

### 6-(5″-Methyl-5′-(5-methylthiophen-2-yl)-[2,2′:4′,2″-terthiophen]-5-yl)-2,3-di-methyl-2,3-dihydrophthalazine-1,4-dione (MeBQPNMe)

Under argon, degassed toluene (15 mL) was added to a suspension of 4,4,5,5-tetramethyl-2-(5″-methyl-5′-(5-methylthiophen-2-yl)-[2,2′:4′,2″-terthiophen]-5-yl)-1,3,2-dioxaborolane (10) (0.8 g, 2 mmol), potassium phosphate tribasic (K₃PO₄, 2 M aqueous solution, 5 mL), tris(dibenzylidene-acetone)dipalladium(0) (Pd₂(dba)₃, 11 mg), tri-tert-butylphosphonium tetrafluoroborate ((tBu)₃P—HBF₄, 15 mg) and 6-bromo-2,3-dimethyl-2,3-dihydrophthalazine-1,4-dione (4) (0.83 g, 3.1 mmol). The solution was heated to reflux for 24 h. After cooling to room temperature, the mixture was poured into water and extracted with methylene chloride. The organic layers were combined, washed with water, dried over MgSO₄, and concentrated under reduced pressure. The product was purified by flash column chromatography (ethyl acetate/methylene chloride, 3:7) followed by recrystallization from chloroform-ethanol (1:1) to get the product as an orange solid in 30% yield (0.262 g): ¹H NMR (DMSO-d₆): δ 8.32 (d, J=1.7 Hz, 1H), 8.23 (dd, J=8.1, 1.7 Hz, 1H), 8.19 (d, J=8.1 Hz, 1H), 7.85 (d, J=3.9 Hz, 1H), 7.58 (s, 1H), 7.50 (d, J=3.9 Hz, 1H), 7.11 (d, J=3.6 Hz, 1H), 7.07 (d, J=3.5 Hz, 1H), 6.83 (d, J=3.2 Hz, 1H), 6.80 (d, J=3.2 Hz, 1H), 3.69 (s, 3H), 3.67 (s, 3H), 2.46 (s, 3H); 2.44 (s, 3H) ppm; ¹³C NMR (DMSO-d₆): δ 156.5, 156.5, 142.3, 140.7, 140.7, 138.0, 137.4, 134.6, 134.0, 133.1, 131.3, 130.1, 130.0, 129.8, 129.2, 128.7, 128.0, 127.9, 127.6, 127.1, 126.7, 126.6, 126.2, 122.8, 33.4, 33.2, 15.5, 15.4 ppm; HRMS (DART-TOF) calculated 547.0637 for C₂₈H₂₃N₂O₂S₄ (M+H)⁺. found 547.0642; elemental analysis calculated N, 5.12; C, 61.51; H, 4.06 and found N, 4.99; C, 61.53; H, 3.90.

The influence of a hydrocarbon moiety for an additional orientation by a hydrocarbon moiety that can self-associate only via van der Waals forces was examined by construction of the molecules:

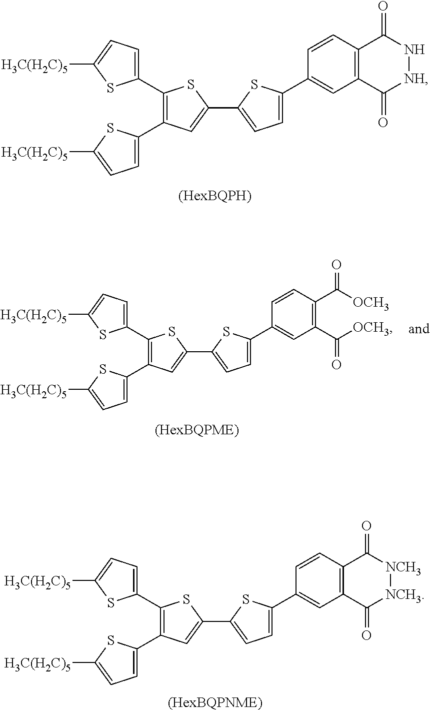

### Synthesis of HexBQP Compounds

### Dimethyl-4-(5″-hexyl-5′-(5-hexylthiophen-2-yl)-[2,2′:4′,2″-terthiophen]-5-yl) phthalate (HexBQPME)

Under argon, degassed toluene (15 mL) was added to a suspension of 4,4,5,5-tetramethyl-2-(5″-hexyl-5′45-hexylthiophen-2-yl)-[2,2′:4′,2″-terthiophen]-5-yl)-1,3,2-dioxaborolane (0.624 g, 1.00 mmol), potassium phosphate tribasic (K₃PO₄, 2 M aqueous solution, 10 mL), tris(dibenzylideneacetone)dipalladium(0) (Pd₂(dba)₃, 7 mg), tri-tert-butylphosphonium tetrafluoroborate ((tBu)₃P—HBF₄, 9 mg) and dimethyl-4-bromophthalate 3 (0.409 g, 1.50 mmol). The solution was heated to reflux for 24 h. After cooling to room temperature, the mixture was poured into water and extracted with methylene chloride (3×100 mL) The organic layers were combined, washed with water, dried over MgSO₄, and concentrated under reduced pressure. The product was purified by flash column chromatography (petroleum ether/CH₂Cl₂, 1:1) and obtained as a yellow solid in 61% yield (0.418 g): ¹H NMR (CDCl₃): δ 7.81 (d, J=1.8 Hz, 1H), 7.72 (d, J=7.9 Hz, 1H), 7.60 (dd, J=8.0, 1.8 Hz, 1H), 7.22 (d, J=3.7 Hz, 1H), 7.17 (s, 1H), 7.05 (d, J=4.1 Hz, 1H), 6.94 (d, J=3.6 Hz, 1H), 6.90 (d, J=3.6 Hz, 1H), 6.67 (dd, J=9.1, 3.6 Hz, 2H), 3.94 (d, J=9.9 Hz, 6H), 2.80 (m, 4H), 1.69 (m, 4H), 1.40 (m, 12H), 0.92 (t, 6H) ppm; ¹³C NMR (CDCl₃): δ 168.1, 167.0, 147.6, 146.4, 140.3, 138.0, 137.0, 134.4, 134.3, 133.7, 132.3, 132.0, 131.2, 130.0, 129.1, 127.5, 126.9, 126.5, 125.7, 125.0, 124.8, 124.3, 124.1, 52.7, 52.5, 31.6, 31.62, 31.61, 31.60, 31.5, 30.2, 28.8, 22.7, 14.1; HRMS (APCI) calculated 690.1960 for C₃₈H₄₂O₄S₄ (M+H)⁺. found 691.2073; elemental analysis calculated C, 66.05; H, 6.13. and found C, 65.68; H, 6.03.

### 6-(5″-Hexyl-5′-(5-hexylthiophen-2-yl)-[2,2′:4′,2″-terthiophen]-5-yl)-2,3-dihydro-phthalazine-1,4-dione (HexBQPH)

Under argon, anhydrous hydrazine (1.75 mL, 36 mmol) was added to a solution of dimethyl-4-(5″-hexyl-5′-(5-hexylthiophen-2-yl)-[2,2′:4′,2″-terthiophen]-5-yl) phthalate (HexBQPME) (0.50 g, 0.72 mmol) in DMF (40 mL). The reaction mixture was heated at 80° C. for 24 h. The reaction mixture was then cooled to 0° C. and ethanol (40 ml) was added. The yellow precipitate formed was isolated by filtration. The precipitate was recrystallized from DMF-ethanol (20 mL/20 mL) to obtain the product as an orange solid in 36% yield (169 mg); ¹H NMR (DMSO-d₆): δ 11.38 (s, 2H), 7.97 (m, 2H), 7.85 (s, 1H), 7.56 (d, J=4.1 Hz, 1H), 7.30 (s, 1H), 7.23 (d, J=4.1 Hz, 1H), 6.84 (d, J=3.6 Hz, 1H), 6.80 (d, J=3.6 Hz, 1H), 6.57 (dd, J=11.8, 3.6 Hz, 2H), 2.28 (m, 4H), 1.35 (m, 4H), 1.08 (m, 12H), 0.63 (t, 6H) ppm; ¹³C NMR (DMSO-d₆): δ 148.3, 146.8, 141.3, 137.5, 134.8, 134.0, 133.4, 131.4, 130.4, 129.8, 129.1, 127.9, 127.8, 127.2, 127.1, 126.9, 126.8, 125.7, 125.2, 31.8, 31.7, 31.6, 31.6, 30.0, 29.99, 28.7, 28.70, 22.7, 14.6 ppm; HRMS (APCI-TOF) calculated 659.1889 for C₃₆H₃₉N₂O₂S₄ (M+H)⁺. found 659.1890; elemental analysis calculated N, 4.25; C, 65.55; H, 5.77 and found N, 4.20; C, 65.76; H, 5.85.

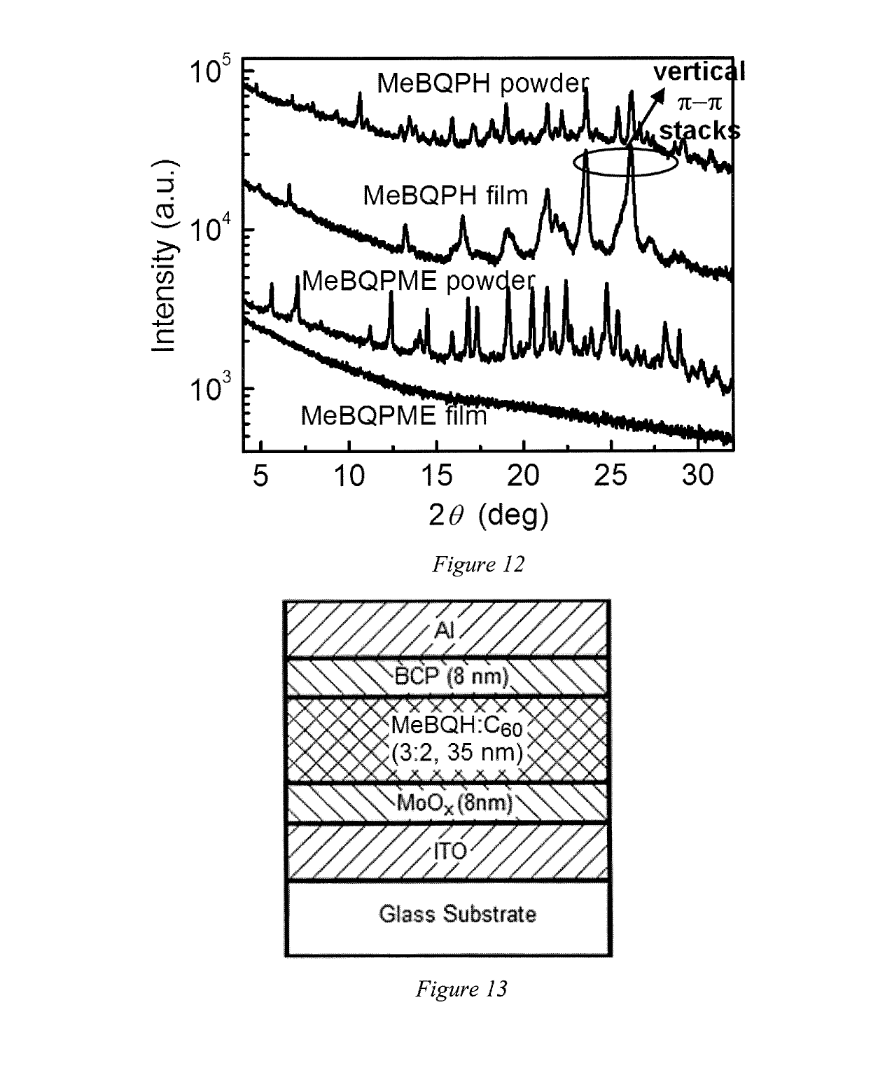

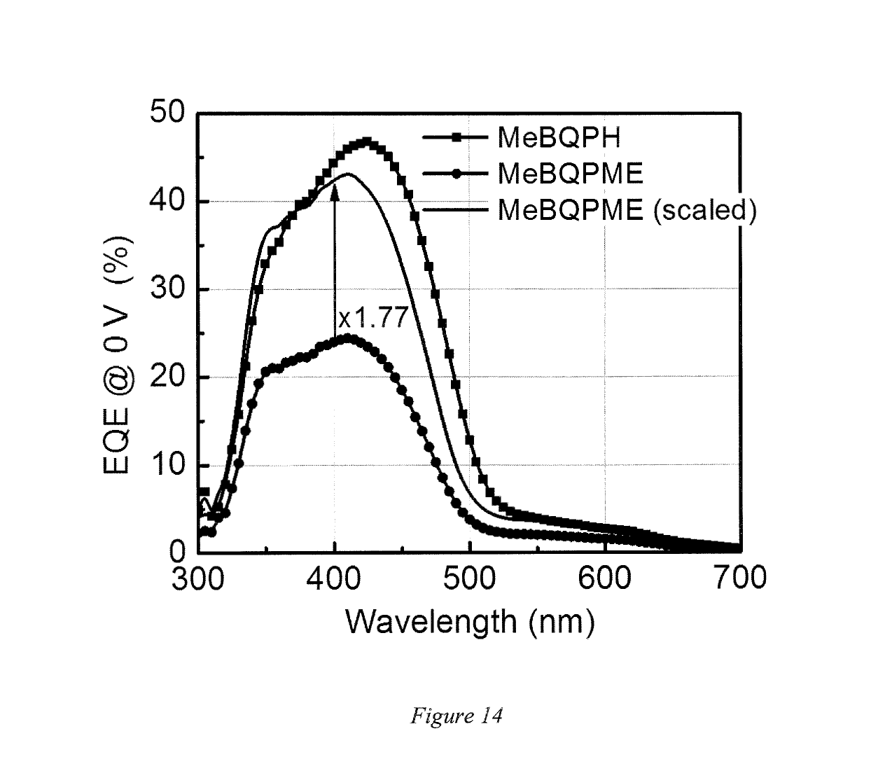

X-ray diffraction experiments were performed to probe the crystal structure of the powders and approximately 1 μm thick films of MeBQPH and MeBQPME. As shown in FIG. 12, the crystalline powders of MeBQPH and MeBQPME display diffraction spectra, indicating different crystal structures. The diffraction pattern for the MeBQPH film contains a few strong peaks. The peaks highlighted in FIG. 14, 2θ=23.5° and 26.1°, correspond to a interplanar spacing of 3.8 Å and 3.4 Å, respectively, which are consistent with the typical stacking distance of extended n-electron systems. This x-ray diffraction pattern is consistent with the stacking of the MeBQPH molecules being normal to the substrate upon which the film was cast. In contrast, the MeBQPME film possesses no discernible diffraction peaks, indicating that the film is amorphous.

MeBQPH and MeBQPME molecules were examined as the electron acceptors in a BHJ with the electron acceptor Cₒ in an organic photovoltaic cell. FIG. 13 shows the device structure of the photovoltaic cell with photoactive layer consisting of a mixture of MeBQPH with C₆₀. FIG. 14 shows a comparison of the external quantum efficiency (EQE) at short-circuit conditions of the cell with MeBQPH and an equivalent cell with MeBQPME. The MeBQPH based device shows a much higher performance, where the EQE curve of the MeTPPH device was more than by a factor of 1.77 greater than that for a MeBQPME device. The two devices display nearly identical EQE at 550 to 600 nm, which is a spectral region that displays absorption for Cₒ but not from MeBQPME or MeBQPH. Again the red-shift of the absorption by MeBQPH is apparent.

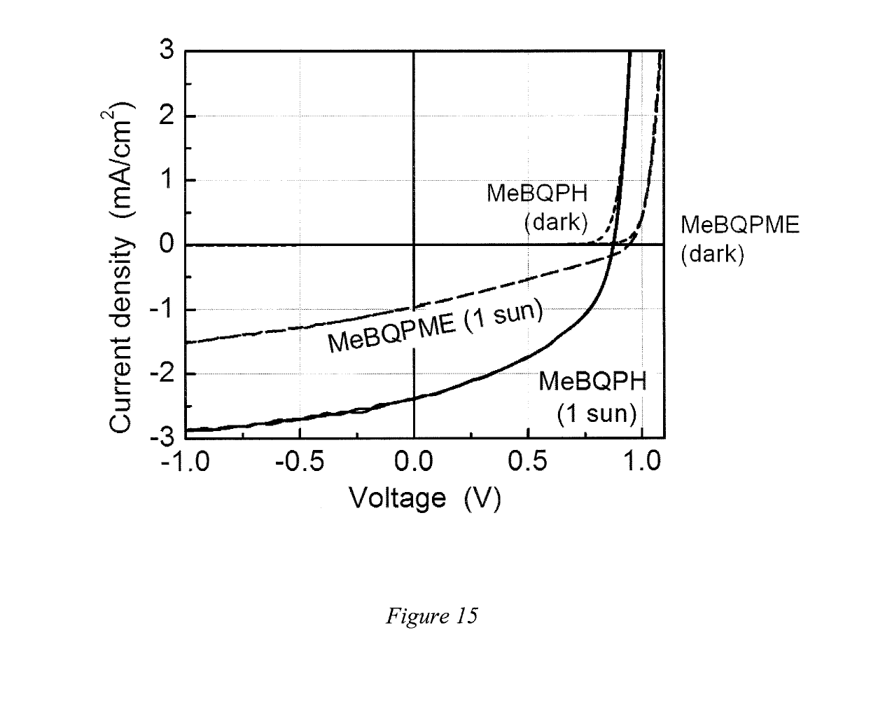

FIG. 15 shows current density-voltage characteristics of two OPV devices in the dark (dashed lines) and under 1 sun simulated AM1.5G solar irradiation (solid lines). The MeBQPH device shows more than twice the short-circuit current density of that of the MeBQPME device, which is consistent with the EQE spectra shown in FIG. 14. Furthermore, the photovoltaic cell fill factor of the MeBQPH device is 0.44, compared to only 0.30 for the MeBQPME device, and is strong evidence that charge transport is significantly better in the MeBQPH device than in the MeBQPME device. Device characteristics for MeBQPH, MeBQPME, and MeBQPNMe with 40 nm thick active layers with C₆₀ acceptor moieties are provided in Table 1, below.

TABLE 1
Device characteristics for MeBQPH, MeBQPME, and MeBQPNMe

| | | J_{SC} | | | |
|---|---|---|---|---|---|
| Molecule | V_{OC} (V) | (mA cm²) | FF (%) | PCE (%) | L_{C} (nm) |
| MeBQPH | 0.87 ± 0.02 | 2.7 ± 0.1 | 44 ± 1 | 1.04 ± 0.07 | 41 ± 4 |
| MeBQPME | 0.92 ± 0.02 | 1.5 ± 0.1 | 35 ± 1 | 0.49 ± 0.05 | 15 ± 2 |
| MeBQPNMe | 0.97 ± 0.02 | 1.7 ± 0.1 | 30 ± 1 | 0.50 ± 0.05 | 19 ± 2 |

OPV device performance under 1 sun AM1.5G illumination: open-circuit voltage (V_{OC}), spectral mismatch adjusted short-circuit current density (J_{SC}), fill factor (FF), power conversion efficiency (PCE), and charge collection length (L_{C}).

### Synthesis of HexLQPH, HexLQPME, and HexLQPNME

To examine the effect of a linear donor moiety the following compounds were prepared:

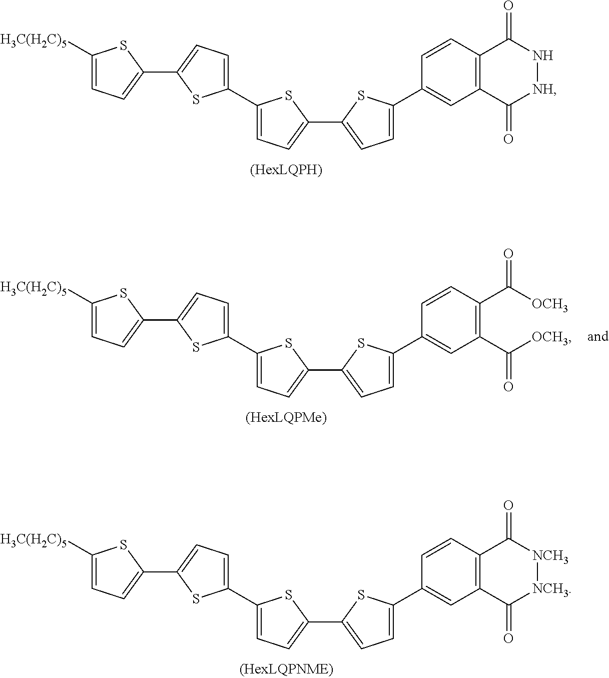

### Synthesis of HexLQPH

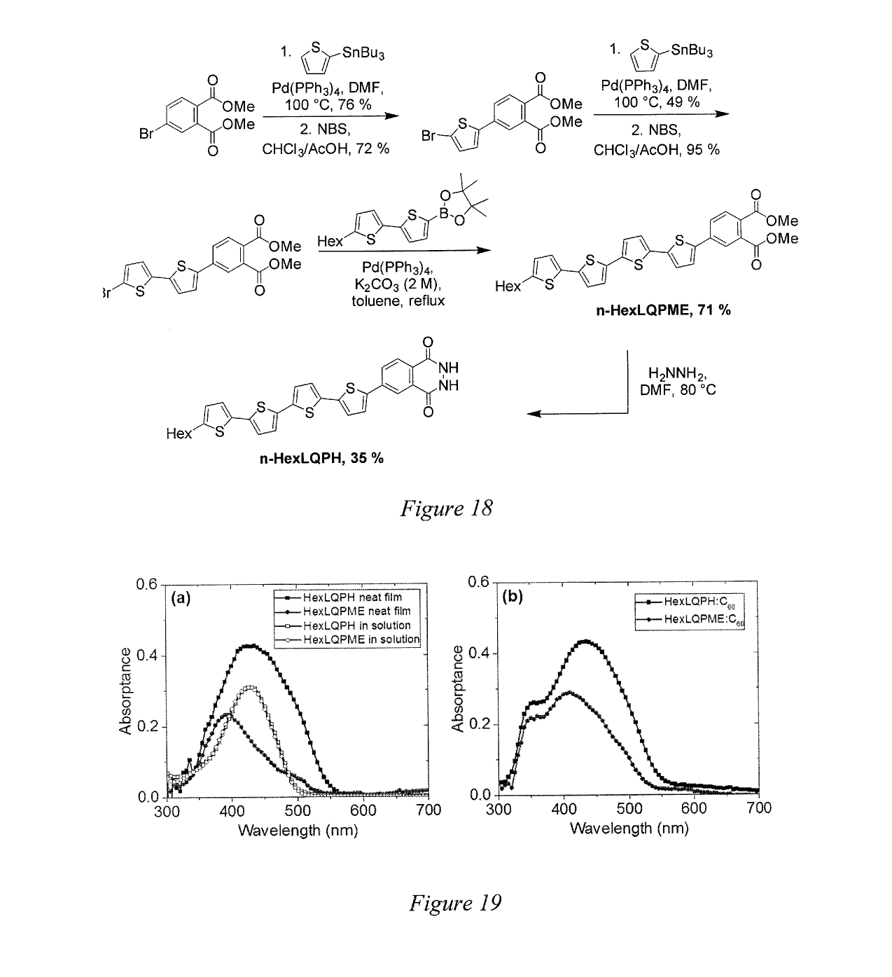

As shown in FIG. 18, Stille coupling between 3 and 2-(tributylstannyl)thiophene provided 2-(dimethylphthalate)thiophene. The corresponding halogenated bithiophene derivative was obtained after consecutive bromination and Stille coupling. Suzuki cross-couplings between the commercially available dioxaborolane and bromonated bithiophene derivatives yielded H-bond inactive congener, HexLQPME. The phthalhydrazide H-bonding derivative, HexLQPH, was prepared in one step from HexLQPME through condensation with hydrazine.

At concentrations of 100 μM in DMF, aggregation via intermolecular H-bonding is not expected. As shown in FIG. 19a, HexLQPH and HexLQPME display very similar absorption profiles with λₘ=426-428 nm and λₒₙₛₑₜ=496-502 nm. The linear quaterthiophene congeners display red shifts in absorption onset as conjugation is extended with replacement of the branched chromophore (λₘₐₓ=393-397 nm and λₒₙₛₑₜ=462-468 nm). The neat film absorption onset of the HexLQPH and HexLQPME molecules is red-shifted relative to MeBQPH, MeBQPME films by 23-25 nm. The absorption spectra of 40 nm thick blended films (1:1 by weight) of HexLQPH:C₆₀ and HexLQPME:C₆₀ are shown in FIG. 18b. The maximum absorption values of 546 and 525 nm for HexLQPH:C₆₀ and HexLQPME:C₆₀, respectively, closely match the values obtained for neat films absent the C₆₀. For MeBQPH:C₆₀ and MeBQPME:C₆₀ films, absorption onsets of 514 and 497 nm, respectively, are blue shifted by 10 and 7 nm from the corresponding neat film absorption absent C₆₀ onsets. Consequently, the addition of C₆₀ does not disrupt the molecular aggregation that gives rise to a red-shifted absorption onset for either HexLQPH or HexLQPME, and the stacking of these molecules with linear donor moieties is disrupted less by the presence of C₆₀ than the molecules with branched donor moieties.

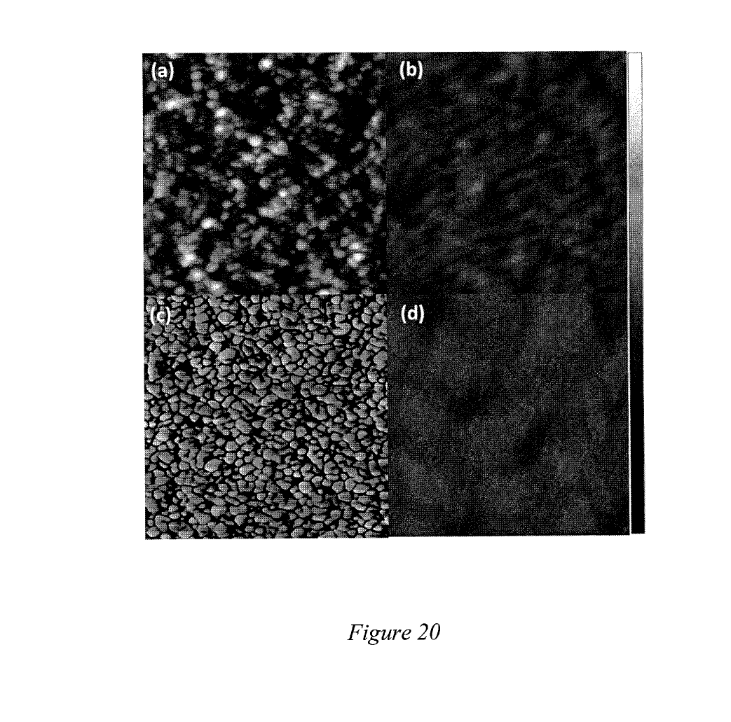

AFM height images of neat HexLQPH and HexLQPME films, shown in FIG. 20, display surfaces covered in nanoscale aggregates with RMS roughnesses of 0.5 and 1.9 nm, respectively. The typical lateral aggregate size is smaller for HexLQPH (20-40 nm) than for HexLQPME (30-70 nm). Furthermore, after annealing for 5 minutes at 100° C., the HexLQPH surface is essentially unchanged, while the HexLQPME aggregates grow to 70-150 nm in cross-section. H-bonding between HexLQPH molecules results in a locked morphology which does not change with light thermal annealing, while HexLQPME molecules much more freely move and reorganize when thermal energy is supplied. This difference provides evidence that the strong H-bonding in these films has a greater effect than does the π-π stacking of the donor moieties and the van der Waals forces of the hydrocarbon moieties of the molecules, and provides the dominant force for directing morphology in HexLQPH films.

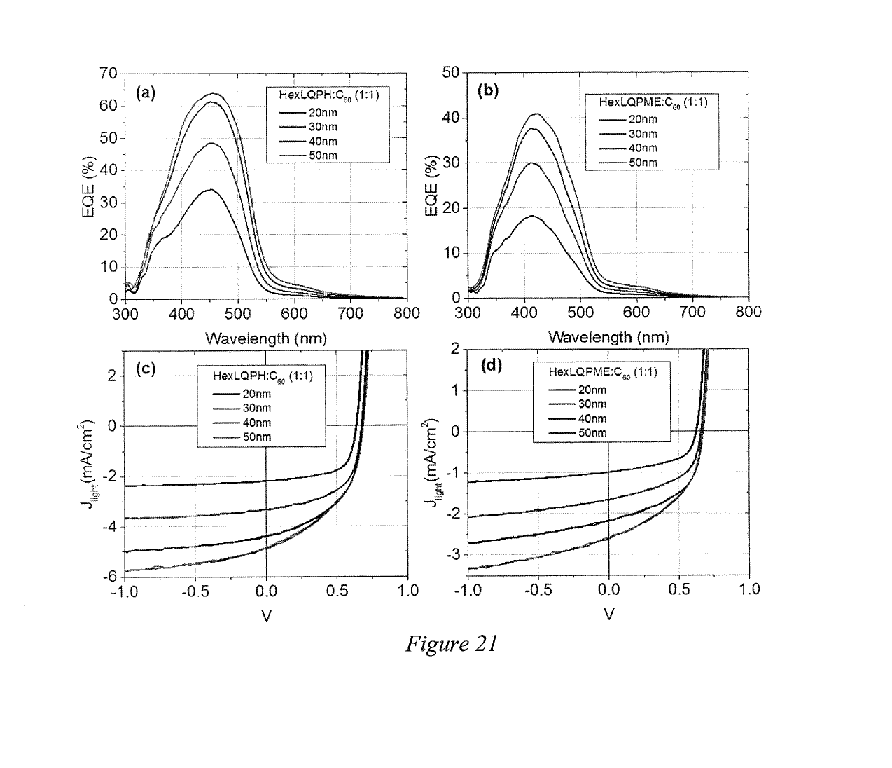

Comparison of devices' performance for HexLQPME and HexLQPH with active layers ranging from 20 to 50 nm are shown in FIG. 21 and summarized in Table 2, below. While the open-circuit voltage (Voc) of these devices are very similar, as expected from DPV measurements, the short-circuit current (Jsc) is dramatically improved for the HexLQPH devices. The fill factor (FF) of the 20 and 30 nm thick HexLQPH devices is improved by 10% and 6% relative to the corresponding HexLQPME devices, while the 40 and 50 nm thick devices incorporating both donors are nearly the same. Overall, the efficiency of devices fabricated from HexLQPH is a factor of 2-3 higher than that of the HexLQPME devices, depending on the thickness.

TABLE 2
Summary of device performance for devices with HexLQPH or HexLQPME
as the donor material with a series of active layer thicknesses

| | Active layer | Voc | | | | | |
|---|---|---|---|---|---|---|---|
| | thickness | (V), | Jsc (mA/cm²), | FF (%), | PCE (%), | L_{c} | η_{cc} |
| Donor | (nm), ±3 nm | ±0.01 V | ±0.05 mA/cm² | ±1% | ±0.05% | (0 V, nm) | (0 V, %) |
| HexLQPH | 20 | 0.64 | 2.18 | 64 | 0.89 | — | — |
| | 30 | 0.67 | 3.32 | 57 | 1.28 | 81 | 84 |
| | 40 | 0.67 | 4.4 | 51 | 1.49 | 83 | 79 |
| | 50 | 0.69 | 4.85 | 45 | 1.51 | 83 | 75 |
| HexLQPME | 20 | 0.63 | 0.99 | 53 | 0.33 | — | — |
| | 30 | 0.66 | 1.67 | 51 | 0.56 | 27 | 61 |
| | 40 | 0.68 | 2.18 | 50 | 0.74 | 29 | 55 |
| | 50 | 0.67 | 2.58 | 46 | 0.79 | 32 | 51 |

Device performances fabricated with linear donors are superior to those of branched donors, as summarized in Table 3. In general, the linear donor devices show lower V_{OC}, but higher J_{SC} and FF than the branched donor devices.

TABLE 3
Summary of device performance for devices with HexLQPH, HexLQPME, MeBQPH or MeBQPME.
All devices have the same structure with a 40 nm thick active layer and a 1:1 blend ratio with C₆₀.

| | Voc (V), | Jsc (mA/cm²), | FF (%), | PCE (%), | L_{c} | η_{cc} |
|---|---|---|---|---|---|---|
| Donor | ±0.01 V | ±0.05 mA/cm² | ±1% | ±0.05% | (0 V, nm) | (0 V, %) |
| HexLQPH | 0.67 | 4.4 | 51 | 1.49 | 83 | 79 |
| HexLQPME | 0.68 | 2.1 | 50 | 0.72 | 29 | 55 |
| MeBQPH | 0.86 | 3.0 | 46 | 1.20 | 59 | 73 |
| MeBQPME | 0.90 | 1.7 | 37 | 0.55 | 34 | 59 |

It should be understood that the examples and embodiments described herein are for illustrative purposes only and that various modifications or changes in light thereof will be suggested to persons skilled in the art and are to be included within the spirit and purview of this application.

We claim:

1. A photoactive layer, comprising:
a supramolecular assembly of donors or acceptors, comprising a plurality of units, where the units comprise a plurality of one or more sub-units, wherein each sub-unit comprises at least one semiconductor moiety, either an electron donor moiety or an electron acceptor moiety, a linking moiety and at least one non-covalent interacting moiety; and
a plurality of complementary electron acceptors or electron donors, wherein the electron acceptors or electron donors fill gaps within the supramolecular assembly of donors or acceptors to form a separate phase within and/or about the units of the supramolecular assembly.

2. The photoactive layer of claim 1, wherein the non-covalent interacting moieties comprise H-bonding moieties, ion-pairing moieties, metal complexing moieties, halogen-bonding moieties, or any combination thereof.

3. The photoactive layer of claim 1, wherein the semiconductor moiety is an electron donor moiety and is a p-type semiconducting π-system.

4. The photoactive layer of claim 3, wherein the π-system comprises a phthalocyanine, naphthalocyanine, subphthalocyanine, oligothiophene, donor-acceptor thiophene-containing oligomer, linear acenes, diindenoperylene, or their derivatives.

5. The photoactive layer of claim 1, wherein the non-covalent interacting moiety comprises phthalhydrazide, guanine, o-benzenedicarboxylic acid, 1,3,5-triazine-2,4-diamine, and guanine-cytosine hybrid.

6. The photoactive layer of claim 1, wherein the non-covalent interacting moiety comprises a H-bonding moiety and further comprises at least one H-bonding partner, wherein the H-bonding moieties form a hetero-association with the H-bonding partner.

7. The photoactive layer of claim 6, wherein the H-bonding moieties comprise melamine and the H-bonding partner comprises cyanuric acid.

8. The photoactive layer of claim 6, wherein the H-bonding moieties comprise uracil and the H-bonding partner comprises melamine.

9. The photoactive layer of claim 6, wherein the H-bonding moieties comprise phthalimide and the H-bonding partner comprises melamine.

10. The photoactive layer of claim 1, wherein the non-covalent interacting moiety comprises a metal complexing moiety and further comprises a metal ion complexed by said metal complexing moiety.

11. The photoactive layer of claim 1, wherein the linking moiety comprises a single, double or triple bond or a unit comprising two functionalities.

12. The photoactive layer of claim 1, wherein each sub-unit comprises a single H-bonding moiety, wherein the unit comprises 2 to 6 sub-units, and wherein the supramolecular assembly of donors or acceptors comprises a plurality of stacked units.

13. The photoactive layer of claim 1, wherein each sub-unit comprises a plurality of non-covalent interacting moieties, wherein the unit comprises a multiplicity of sub-units in the form of a sheet, and wherein the supramolecular assembly of donors or acceptors comprises a plurality of stacked units.

14. The photoactive layer of claim 1, wherein the supramolecular assembly of donors and the plurality of electron acceptors that fill gaps within the supramolecular assembly of donors provide continuous parallel nanophases of the electron donors for hole percolation and the electron acceptors for electron percolation through the photoactive layer, wherein hole-electron recombination is at least partially inhibited.

15. The photoactive layer of claim 1, wherein the electron acceptors comprise: [6,6]-phenyl-C61 butyric acid methyl ester (PCBM); phenyl-C71-butyric-acid-methyl ester (bis[70]PCBM); CdSe nanoparticles; CdS nanoparticles; PbSe nanoparticles; ZnO nanocrystals; titania; electron-deficient pentacenes; terrylene-3,4:11,12-bis(dicarboximide) (TDI); 3,4,9,10-perylenetetracarboxylic-bis-benzimidazole (PTCBI), perylene-3,4,9,10-tetracarboxylic-3,4,9,10-dianhydride (PTCDA), and perylene-3,4,9,10-tetracarboxylic-3,4,9,10-diimide (PTCDI); poly((9,9-dioctylfluorene)-2,7-diyl-alt-[4,7-bis(3-hexylthien-5-yl)-2,1,3-benzothiadiazole]-2,2-diyl) (F8TBT); or 1,4-diaminoanthraquinone (1,4-DAAQ).

16. The photoactive layer of claim 1, wherein the sub-unit comprises:

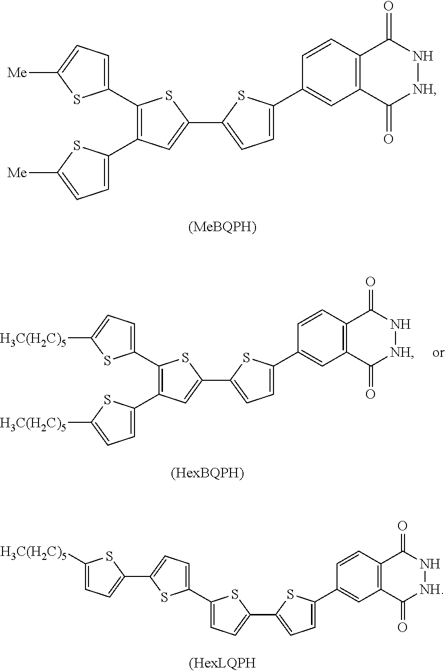

17. An organic photovoltaic (OPV) device, comprising a photoactive layer according to claim 1.

18. A method of forming an active layer according to claim 1, comprising:
providing a plurality of sub-units;
providing a plurality of electron acceptors or electron donors;
depositing the sub-units;
depositing the electron acceptors or electron donors; and
promoting the formation of units from the sub-units, wherein a supramolecular assembly of donors or acceptors forms that is mixed as a separate phase to the electron acceptors or electron donors.

19. The method of claim 18, wherein the sub-units are provided in solution and depositing the sub-units comprises spin coating, inkjet printing, or spray coating.

20. The method of claim 18, wherein the electron acceptors are provided in solution, and depositing the electron acceptors comprises spin coating, inkjet printing, or spray coating.

21. The method of claim 18, wherein sub-units are provided in bulk and depositing the sub-units comprises vacuum thermal evaporation, organic vapor phase deposition, or organic vapor jet printing.

22. The method of claim 18, wherein electron acceptors are provided in bulk and depositing the electron acceptors comprises vacuum thermal evaporation, organic vapor phase deposition, or organic vapor jet printing.

23. The method of claim 18, wherein the sub-units and the electron acceptors or electron donors are deposited simultaneously or sequentially.
